(19) United States
(12) Patent Application Publication
(10) Pub. No.: US 2022/0328671 A1
(43) Pub. Date: Oct. 13, 2022

(54) FIELD EFFECT TRANSISTOR STRUCTURE

(71) Applicant: Samsung Electronics Co., Ltd., Suwon-si (KR)

(72) Inventors: Changhyun KIM, Seoul (KR); Hyeonjin SHIN, Suwon-si (KR); Minhyun LEE, Suwon-si (KR); Taejin CHOI, Suwon-si (KR); Sangwon KIM, Seoul (KR); Bongseob YANG, Hwaseong-si (KR); Eunkyu LEE, Yongin-si (KR)

(73) Assignee: Samsung Electronics Co., Ltd., Suwon-si (KR)

(21) Appl. No.: 17/539,768

(22) Filed: Dec. 1, 2021

(30) Foreign Application Priority Data
Apr. 13, 2021 (KR) 10-2021-0048024

(51) Int. Cl. H01L 29/76; H01L 27/092; H01L 29/06; H01L 29/423; H01L 29/786; H01L 29/16; H01L 29/20; H01L 29/24

(52) U.S. Cl. CPC H01L 29/7606; H01L 27/0922; H01L 29/0665; H01L 29/42392; H01L 29/78696; H01L 29/1606; H01L 29/2003; H01L 29/24

(57) ABSTRACT

A field effect transistor structure is disclosed. The field effect transistor structure includes: a fin-shaped channel protruding from a substrate and extending in one direction; a source electrode on one side of the fin-shaped channel; a drain electrode separated from the source electrode with the fin-shaped channel therebetween; a gate insulating film surrounding side and upper surfaces of the fin-shaped channel; a gate electrode on the gate insulating film; and a two-dimensional semiconductor material layer between the gate insulating film and the gate electrode.

### CROSS-REFERENCE TO RELATED APPLICATION

This application is based on and claims priority under 35 U.S.C. § 119 to Korean Patent Application No. 10-2021-0048024, filed on Apr. 13, 2021, in the Korean Intellectual Property Office, the disclosure of which is incorporated by reference herein in its entirety.

### BACKGROUND

### 1. Field

The present disclosure relates to field effect transistor structures.

### 2. Description of the Related Art

A transistor is a semiconductor device that performs electrical switching and is used in various integrated circuit devices, such as memories, driver integrated circuits (ICs), logic devices, etc. In order to increase the degree of integration of an integrated circuit device, a space occupied by transistors provided therein has been rapidly reduced. Accordingly, research has been conducted to reduce the size of the transistors while maintaining their performance.

One of the important parts of a transistor is a gate electrode. When a voltage is applied to the gate electrode, a channel adjacent to a gate opens a path for a current. In an opposite case, the channel may block the current when no voltage is applied to the gate. The performance of a semiconductor may depend on how much a leakage current is reduced and efficiently managed in a gate electrode and a channel. The greater the contact area between a channel and a gate electrode that controls a current in a transistor, the higher the power efficiency.

On the other hand, as the semiconductor processes may be minute, the size of a transistor may be reduced and also the area where the gate electrode and the channel that contact each other may be reduced; thus, problems due to a short channel effect may be caused. For example, various phenomena may occur, such as threshold voltage variations. Accordingly, methods for overcoming a short channel effect as well as reducing the size of the transistor have been sought.

### SUMMARY

Provided are field effect transistor structures capable of reducing the size of a field effect transistor and/or controlling a threshold voltage.

Provided are field effect transistor structures capable of having various threshold voltages.

Additional aspects will be set forth in part in the description which follows and, in part, will be apparent from the description, or may be learned by practice of the presented embodiments of the disclosure.

According to an embodiment, a field effect transistor structure may include a fin-shaped channel protruding from a substrate and extending in one direction, a source electrode on one side of the fin-shaped channel, a drain electrode separated from the source electrode with the fin-shaped channel therebetween, a gate insulating film surrounding side and upper surfaces of the fin-shaped channel, a gate electrode arranged on the gate insulating film, and a two-dimensional semiconductor material layer arranged between the gate insulating film and the gate electrode.

In some embodiments, the two-dimensional semiconductor material layer may have a thickness of about 3 nm or less.

In some embodiments, the gate electrode may include one or more of a metal, a metal-carbide, a metal-nitride, a metal-silicide, a metal-silicon-nitride, silicon, and a graphene-based material.

In some embodiments, the two-dimensional semiconductor material layer may include at least one of graphene, black phosphorus, amorphous boron nitride, two-dimensional hexagonal boron nitride (h-BN), phosphorene, or a transition metal dichalcogenide.

In some embodiments, the transition metal dichalcogenide may include one metal element and one chalcogen element. The one metal element may be selected from the group consisting of Mo, W, Nb, V, Ta, Ti, Zr, Hf, Tc, Re, Cu, Ga, In, Sn, Ge, and Pb. The one chalcogen element may be selected from the group consisting of S, Se, and Te.

In some embodiments, the two-dimensional semiconductor material layer may include: amorphous boron nitride having a grain size of about 20 nm or less, or hexagonal boron nitride (h-BN) having a grain size of about 20 nm or less.

According to an embodiment, a field effect transistor structure may include a first field effect transistor and a second field effect transistor adjacent to each other. The first field effect transistor may include a fin-shaped first channel protruding from a substrate and extending in one direction, a first source electrode on one side of the fin-shaped first channel, a first drain electrode separated from the first source electrode with the fin-shaped first channel therebetween, a first gate insulating film surrounding side and upper surfaces of the fin-shaped first channel, and a first gate electrode on the first gate insulating film. The second field effect transistor may include a fin-shaped second channel protruding from the substrate and extending in the one direction, a second source electrode on one side of the fin-shaped second channel, a second drain electrode separated from the second source electrode with the fin-shaped second channel therebetween, a second gate insulating film surrounding side and upper surfaces of the fin-shaped second channel, a second gate electrode on the second gate insulating film, and a second two-dimensional semiconductor material layer between the second gate insulating film and the second gate electrode.

In some embodiments, the first field effect transistor may further include a first two-dimensional semiconductor material layer between the first gate insulating film and the first gate electrode, and the first two-dimensional semiconductor material layer and the second two-dimensional semiconductor material layer may include different two-dimensional semiconductor materials.

In some embodiments, the first field effect transistor may further include a first two-dimensional semiconductor material layer between the first gate insulating film and the first gate electrode, and the first two-dimensional semiconductor material layer and the second two-dimensional semiconductor material layer have different thicknesses.

In some embodiments, the first two-dimensional semiconductor material layer and the second two-dimensional semiconductor material layer each may have a thickness of about 3 nm or less.

According to an embodiment, a field effect transistor structure may include a channel extending in one direction parallel to a substrate, a source electrode on one side of the channel, a drain electrode separated from the source electrode with the channel therebetween, a gate insulating film surrounding the channel, a gate electrode on the gate insulating film, and a two-dimensional semiconductor material layer between the gate insulating film and the gate electrode.

In some embodiments, the channel may be one channel among a plurality of channels arranged in a direction perpendicular to the substrate.

In some embodiments, the two-dimensional semiconductor material layer may have a thickness of about 3 nm or less.

In some embodiments, the gate electrode may include one or more of a metal, a metal-carbide, a metal-nitride, a metal-silicide, a metal-silicon-nitride, silicon, and a graphene-based material.

In some embodiments, the two-dimensional semiconductor material layer may include one or more of graphene, black phosphorus, amorphous boron nitride, two-dimensional hexagonal boron nitride (h-BN), phosphorene, or a transition metal dichalcogenide.

In some embodiments, the transition metal dichalcogenide may include one metal element and one chalcogen element. The one metal element may be selected from the group consisting of Mo, W, Nb, V, Ta, Ti, Zr, Hf, Tc, Re, Cu, Ga, In, Sn, Ge, and Pb. The one chalcogen element may be selected from the group consisting of S, Se, and Te.

In some embodiments, the two-dimensional semiconductor material layer may include: amorphous boron nitride having a grain size of about 20 nm or less, or two-dimensional hexagonal boron nitride having a grain size of about 20 nm or less.

In some embodiments, the channel may have a nanowire shape extending in one direction.

In some embodiments, the channel may have a nano-sheet shape extending along one plane.

According to an embodiment, a field effect transistor structure may include a first field effect transistor and a second field effect transistor adjacent to each other. The first field effect transistor may include a first channel extending in one direction parallel to a substrate, a first source electrode on one side of the first channel, a first drain electrode separated from the first source electrode with the first channel therebetween, a first gate insulating film surrounding the first channel, and a first gate electrode on the first gate insulating film. The second field effect transistor may include a second channel extending in the one direction parallel to the substrate, a second source electrode on one side of the first channel, a second drain electrode separated from the second source electrode with the second channel therebetween, a second gate insulating film surrounding the first channel, a second gate electrode on the second gate insulating film, and a second two-dimensional semiconductor material layer between the second gate insulating film and the second gate electrode.

In some embodiments, the first field effect transistor may further include a first two-dimensional semiconductor material layer between the first gate insulating film and the first gate electrode. The first two-dimensional semiconductor material layer and the second two-dimensional semiconductor material layer include different two-dimensional semiconductor materials.

In some embodiments, the first field effect transistor may further include a first two-dimensional semiconductor material layer arranged between the first gate insulating film and the first gate electrode. The first two-dimensional semiconductor material layer and the second two-dimensional semiconductor material layer have different thicknesses.

In some embodiments, the first two-dimensional semiconductor material layer and the second two-dimensional semiconductor material layer each may have a thickness of about 3 nm or less.

According to an embodiment, a field effect transistor structure may include a substrate; a channel structure on the substrate, the channel structure being a fin-shaped channel protruding from the substrate or at least one nano-sheet above the substrate; a source electrode on one side of the channel structure; a drain electrode separated from the source electrode with the channel structure therebetween; a gate insulating film on the channel structure; a gate electrode on the gate insulating film; and a two-dimensional semiconductor material layer between the gate insulating film and the gate electrode.

In some embodiments, the two-dimensional semiconductor material layer may have a thickness of about 3 nm or less.

In some embodiments, the two-dimensional semiconductor material layer may include at least one of graphene, black phosphorus, amorphous boron nitride, two-dimensional hexagonal boron nitride (h-BN), phosphorene, or a transition metal dichalcogenide.

In some embodiments, the two-dimensional semiconductor material may include: amorphous boron nitride having a grain size of about 20 nm or less, or two-dimensional hexagonal boron nitride having a grain size of about 20 nm or less.

In some embodiments, the field effect transistor structure may include a plurality of channel structures on the substrate, a plurality of gate insulating films on the substrate, a plurality of gate electrodes on the substrate, and a plurality of two-dimensional semiconductor material layers on the substrate. The channel structure on the substrate may be a first channel structure and the plurality of channel structures may include a second channel structure on the substrate spaced apart from the first channel structure. The gate insulating film may be a first gate insulating film among the plurality of gate insulating films. The plurality of gate insulating films may include a second gate insulating film on the second channel structure. The gate electrode may be a first gate electrode among the plurality of gate electrodes. The plurality of gate electrodes may include a second gate electrode on the second gate insulating film. The two-dimensional material semiconductor layer may be a first two-dimensional material layer among the plurality of two-dimensional material layers. The plurality of two-dimensional semiconductor layers may include a second two-dimensional semiconductor layer between the second gate insulating film and the second gate electrode.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view showing a field effect transistor structure according to an embodiment;

FIG. 2 is a cross-sectional view taken along line A-A of the field effect transistor structure of FIG. 1;

FIG. 3 is a graph showing a work function according to a comparative example and an embodiment;

FIG. 4 is a cross-sectional view taken along line A-A of the field effect transistor structure of FIG. 1, according to another embodiment;

FIG. 5 is a cross-sectional view taken along line A-A of the field effect transistor structure of FIG. 1, according to another embodiment;

FIG. 6 is a schematic perspective view showing a field effect transistor structure according to an embodiment;

FIG. 7 is a cross-sectional view taken along line B-B of the electric field effect transistor structure of FIG. 6;

FIG. 8 is a schematic cross-sectional view of a field effect transistor structure according to another embodiment;

FIG. 9 is a schematic cross-sectional view of a field effect transistor structure according to another embodiment;

FIG. 10 is a schematic cross-sectional view of a field effect transistor structure according to another embodiment;

FIG. 11 is a schematic block diagram of a display device including a display driver integrated circuit (DDIC) and a DDI according to an embodiment;

FIG. 12 is a circuit diagram of a CMOS inverter according to an embodiment;

FIG. 13 is a circuit diagram of a CMOS SRAM device according to an embodiment;

FIG. 14 is a circuit diagram of a CMOS NAND circuit according to an embodiment;

FIG. 15 is a block diagram of an electronic system according to an embodiment;

and

FIG. 16 is a block diagram of an electronic system according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” “at least one of A, B, or C,” “one of A, B, C, or a combination thereof,” and “one of A, B, C, and a combination thereof,” respectively, may be construed as covering any one of the following combinations: A; B; A and B; A and C; B and C; and A, B, and C.”

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, field effect transistors and methods of manufacturing the field effect transistors according embodiments will be described in detail with reference to the accompanying drawings. In the drawings, like reference numerals refer to like elements, and the size of each component may be exaggerated for clarity and convenience of explanation. It will be understood that, although the terms “first”, “second”, etc. may be used herein to describe various elements, these elements should not be limited by these terms. These terms are only used to distinguish one element from another.

In the following descriptions, the singular forms include the plural forms unless the context clearly indicates otherwise. When a part “comprises” or “includes” an element in the specification, unless otherwise defined, it is not excluding other elements but may further include other elements. Sizes or thicknesses of constituent elements in the drawings may be exaggerated for clarity of explanation. Further, when a desired and/or alternatively predetermined material layer is present on a substrate or another layer, the material layer may be present in direct contact with the substrate or other layer, and there may be a third layer therebetween. Also, in the following embodiments, a material included in each layer is example, that is, other materials may be included.

Also, in the specification, the term “units” or “ . . . modules” denote units or modules that process at least one function or operation, and may be realized by hardware, software, or a combination of hardware and software.

Specific executions described in the present disclosure are example embodiments and do not limit the technical scope of inventive concepts. For conciseness of the specification, descriptions of conventional electronic configurations, control systems, software, and other functional aspects of the systems may be omitted.

Also, the connections of lines and connection members between constituent elements depicted in the drawings are examples of functional connection and/or physical or circuitry connections, and thus, in practical devices, may be expressed as replicable or additional functional connections, physical connections, or circuitry connections.

The term “above” and similar directional terms may be applied to both singular and plural.

Operations of all methods described herein may be performed in any suitable order unless otherwise indicated herein or otherwise clearly contradicted by context. The use of any and all examples, or other example language (e.g., “such as”) provided herein, is intended merely to better illuminate inventive concepts and does not pose a limitation on the scope of inventive concepts unless otherwise claimed.

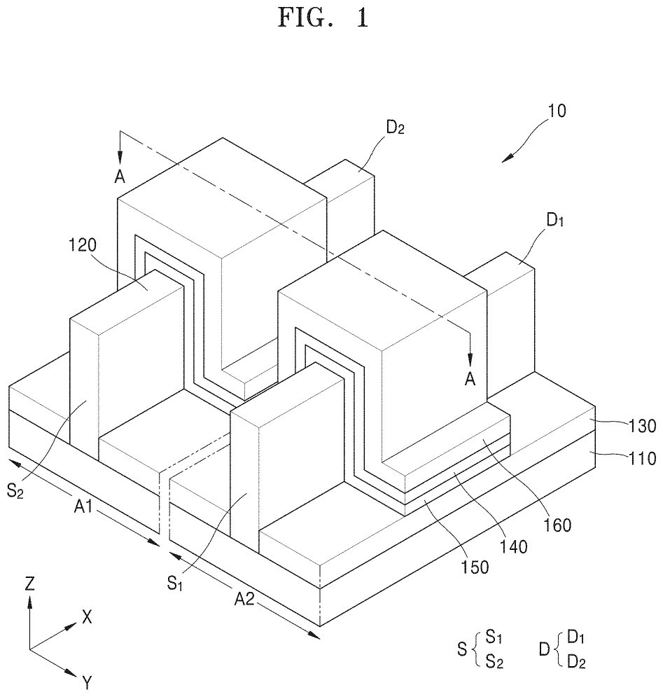

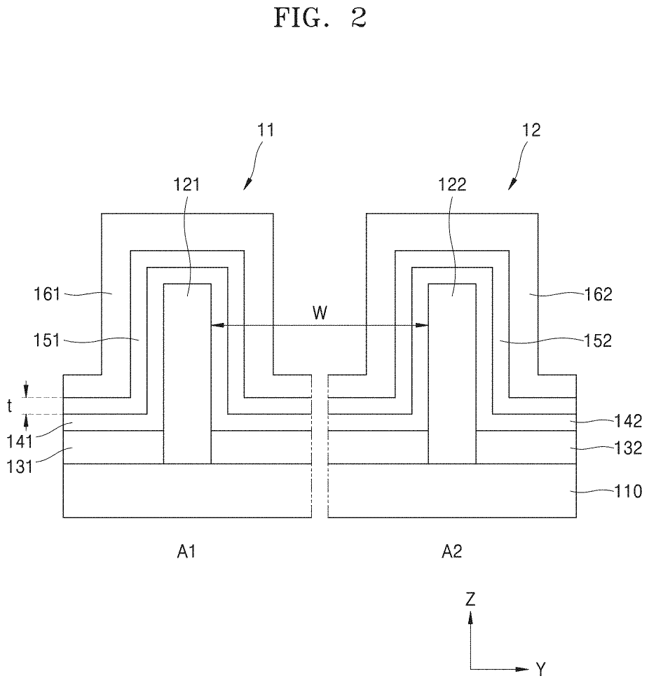

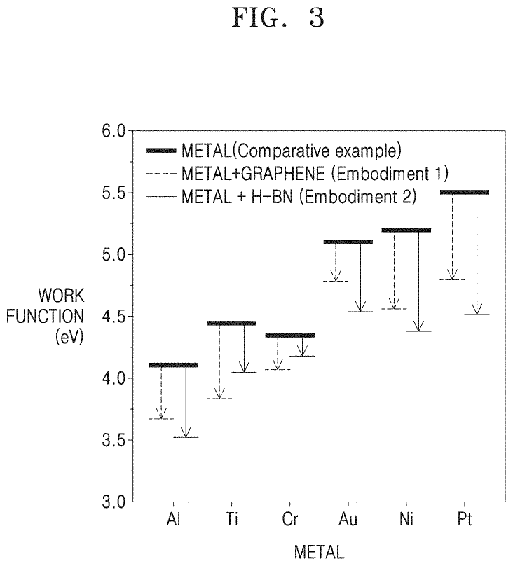

FIG. 1 is a schematic perspective view showing a field effect transistor structure 10 according to an embodiment. FIG. 2 is a cross-sectional view taken along line A-A of the field effect transistor structure 10 of FIG. 1. The cross section A-A may represent a cross section cut in a vertical direction to a substrate 110 (a Z-direction in the drawing) across (a Y-direction in the drawing) between a source electrode S and a drain electrode D. Here, since the substrate 110 may not be a completely planar, the vertical direction may include a substantially vertical direction as well as a general vertical direction. FIG. 3 is a graph showing a work function according to a comparative example and an embodiment.

Referring to FIGS. 1 and 2, the field effect transistor structure 10 according to an embodiment includes the substrate 110, a channel 120 on the substrate 110, a source electrode S and a drain electrode D arranged on both sides of the channel 120, a gate insulating film 140, a two-dimensional (2D) semiconductor material layer 150, and a gate electrode 160 arranged to be insulated from the source electrode S and the drain electrode D. According to an embodiment, the field effect transistor structure 10 may be provided as a fin field effect transistor (FinFET).

The substrate 110 may be an insulating substrate, or may be a semiconductor substrate having an insulating layer on a surface thereof. The semiconductor substrate may include, for example, Si, Ge, SiGe or Group III-V semiconductor material, etc. The substrate 110 may be, for example, a silicon substrate having a silicon oxide on a surface thereof, but is not limited thereto.

The channel 120 may be formed to protrude in a first direction (the Z-direction) from an upper surface of the substrate 110. As an example, the channel 120 may be formed in a fin-shape extending in a second direction (an X-direction). For example, the channel 120 may be formed by patterning a desired and/or alternatively predetermined region of the substrate 110. However, the present disclosure is not limited thereto.

The channel 120 according to an embodiment may be provided in a plural number. For example, as shown in FIG. 2, the channel 120 may include a first channel 121 and a second channel 122 provided in a first region A1 and a second region A2, respectively. At this time, a first field effect transistor 11 including the first channel 121 may be arranged in the first region A1 of the field effect transistor structure 10 according to an embodiment, and a second field effect transistor 12 including the second channel 122 may be arranged in the second region A2. In FIGS. 1 and 2, the field effect transistor structure 10 is illustrated as including two field effect transistors 11 and 12, but the present disclosure is not limited thereto. The field effect transistor structure 10 according to an embodiment may have one field effect transistor or may have three or more field effect transistors.

The first channel 121 and the second channel 122 may be arranged so as to be separated from each other with a desired and/or alternatively predetermined gap therebetween in a third direction (the Y-direction). A device isolation film 130 may be arranged between the first channel 121 and the second channel 122. As an example, the device isolation film 130 may be arranged to extend along one plane (an XY plane). For example, the device isolation film 130 may include a silicon oxide (SiOx) film. For example, when a plurality of channels 120 are provided as shown in FIG. 2, the device isolation film 130 may also include a first device isolation film 131 and a second device isolation film 132 respectively arranged in the first region A1 and the second region A2.

The source electrode S may be provided on the substrate 110, and the drain electrode D may be arranged to be separated from the source electrode S with the channel 120 therebetween. According to an example, the source electrode S and the drain electrode D may be arranged on both sides of the channel 120 to be separated in the second direction (the X-direction). As an example, the source electrode S and the drain electrode D may be respectively formed on both sides of the fin-shaped channel 120 before forming the gate electrode 160, which will be described later. Also, as an example, when a plurality of channels 120 are provided as shown in FIG. 2, the first source electrode S1 and the first drain electrode D1, and the second source electrode S2 and the second drain electrode D2 may be respectively formed on both sides of the first channel 121 and the second channel 122 arranged in the first region A1 and the second region A2, respectively.

According to an example, an etch stop layer (not shown) is optionally formed on both sides of the channel 120 where the source electrode S and the drain electrode D are to be formed. Thereafter, a dummy gate film may be formed to completely cover the channel 120 and the etch stop layer (not shown). The channel 120 of a region where the source electrode S and the drain electrode D to be formed is exposed by etching the dummy gate film. Thereafter, the source electrode S and the drain electrode D may be formed by injecting an N-type or a P-type dopant into the exposed channel 120.

The gate insulating film 140 may be arranged between the channel 120 and the gate electrode 160 which will be described later. As an example, the gate insulating film 140 may be formed to surround side and upper surfaces of the channel 120. In addition, the gate insulating film 140 may extend in the third direction (the Y-direction). The gate electrode 160, which will be described later, may be insulated from the source electrode S and the drain electrode D by the gate insulating film 140. The gate insulating film 140 may be a dielectric film having a high dielectric constant high-k (e.g., an insulating material having a higher dielectric constant than silicon oxide, such as hafnium oxide or zirconium oxide). The gate insulating film 140 may include, for example, one or more of a metal-oxide including HF or Zr, a metal-oxide-nitride including HF or Zr, or a material that is formed by doping Ti, Ta, Al, or a lanthanide-based material to the above materials. Also, as an example, when the plurality of channels 120 are arranged as shown in FIG. 2, the gate insulating film 140 may also include a first gate insulating film 141 and a second gate insulating film 142 respectively arranged in the first region A1 and the second region A2.

The gate electrode 160 may be arranged on the gate insulating film 140. As an example, the gate electrode 160 extends in the third direction (the Y-direction) which is a direction of extending the gate insulating film 140, and may be conformally formed across an upper and side surfaces of the channel 120. Accordingly, a channel region may be formed in the channel 120 in a horizontal direction (e.g., the X-direction) and a vertical direction (e.g., the Z-direction). As shown in FIG. 2, when the channel 120 according to an embodiment is provided in a plural number, the gate electrode 160 may also include a first gate electrode 161 and a second gate electrode 162 respectively arranged in the first region A1 and the second region A2.

As an example, the gate electrode 160 may include one or more of a metal, a metal-carbide, a metal-nitride, a metal-silicide, a metal-silicon-nitride, silicon, and a graphene material. At this time, the gate electrode 160 may have a desired and/or alternatively predetermined work function. A threshold voltage of the field effect transistor structure 10 according to an embodiment may be controlled by using the work function of the gate electrode 160.

The field effect transistor structure 10 according to an embodiment may be provided as a three-dimensional (3D) structure, such as a fin-field effect transistor. Due to the 3D shape of the field effect transistor structure 10, a reliable control of the work function of the gate electrode 160 may be difficult. As an example, in order to improve the degree of integration of the field effect transistor structure 10, a gap between the channels 120, for example, a gap W between the first channel 121 arranged in the first region A1 and the second channel 122 arranged in the second region A2 may be reduced. At this time, in a process of depositing the gate electrode 160 between the first channel 121 and the second channel 122, the reliable deposition of the gate electrode 160 for controlling the work function may be difficult. According to an embodiment, in the field effect transistor structure 10 provided in a 3D structure, in order to control a threshold voltage of the field effect transistor structure 10, the 2D semiconductor material layer 150 may be arranged between the gate insulating film 140 and the gate electrode 160.

The 2D semiconductor material layer 150 may be arranged between the gate insulating film 140 and the gate electrode 160 to control a threshold voltage of the field effect transistor structure 10. As an example, the 2D semiconductor material layer 150 may include graphene, a 2D hexagonal boron nitride (h-BN), black phosphorus, phosphorene, or transition metal dichalcogenide. As an example, an amorphous boron nitride or the 2D hexagonal boron nitride (h-BN) may have a grain size of about 20 nm or less. In addition, the transition metal dichalcogenide may include one or more metal element selected from the group consisting of Mo, W, Nb, V, Ta, Ti, Zr, Hf, Tc, Re, Cu, Ga, In, Sn, Ge, and Pb and one or more chalcogen element selected from the group consisting of S, Se, and Te. On the other hand, a desired and/or alternatively predetermined conductive dopant may be doped to a 2D semiconductor material.

As an example, when the 2D semiconductor material layer 150 is arranged to overlap with the gate electrode 160, a work function of the 2D semiconductor material layer 150 and the gate electrode 160 may be reduced. Referring to FIG. 3, in the comparative example, the gate electrode 160 having a thickness includes only a metal material, and a separate 2D semiconductor material layer 150 is not arranged. On the other hand, in embodiment 1, the 2D semiconductor material layer 150 having a thickness of 0.33 nm and including a graphene material is arranged on the gate electrode 160 including a metal material having a thickness. In embodiment 2, the 2D semiconductor material layer 150 having a thickness of 0.33 nm and including a 2D hexagonal boron nitride (h-BN) is arranged on the gate electrode 160 including a metal material having a thickness.

As may be seen in FIG. 3, in the comparative example, in which only the gate electrode 160 is arranged, it may be confirmed that a high work function is measured. On the other hand, in embodiments 1 and 2, in which the 2D semiconductor material layer 150 is arranged on the gate electrode 160, it may be confirmed that a work function lower than that of the comparative example is measured. Therefore, the work function may be reduced by arranging the 2D semiconductor material layer 150 of an ultra-thin film on the gate electrode 160, and accordingly, a threshold voltage of the field effect transistor structure 10 may be controlled.

As an example, the 2D semiconductor material layer 150 may extend in the third direction (the Y-direction), which is a direction of extending the gate insulating film 140. The 2D semiconductor material layer 150 according to an embodiment may be provided in the form of an ultra-thin film as described above. For example, the thickness t of the 2D semiconductor material layer 150 may be about 3 nm or less. For example, the thickness t of the 2D semiconductor material layer 150 may be about 2 nm or less. For example, the thickness t of the 2D semiconductor material layer 150 may be about 1 nm or less. When the plurality of channels 120 according to an embodiment is provided as shown in FIG. 2, the 2D semiconductor material layer 150 may also include a first 2D semiconductor material layer 151 and a second 2D semiconductor material layer 152 respectively arranged in the first region A1 and the second region A2.

As described above, in order to improve the degree of integration of the field effect transistor structure 10, the gap between the channels 120, for example, the gap W between the first channel 121 arranged in the first region A1 and the second channel 122 arranged in the second region A2 is reduced. However, as the 2D semiconductor material layer 150 according to an embodiment is provided in the form of an ultra-thin film, the 2D semiconductor material layer 150 between the first channel 121 and the second channel 122 may be easily arranged. Accordingly, a threshold voltage of the field effect transistor structure 10 may be controlled without changing the gate electrode 160. Hereinafter, a technical feature of individually controlling threshold voltages of the first field effect transistor 11 arranged in the first region A1 and the second field effect transistor 12 arranged in the second region A2 will be described by using the first 2D semiconductor material layer 151 and the second 2D semiconductor material layer 152 respectively arranged in the first region A1 and the second region A2.

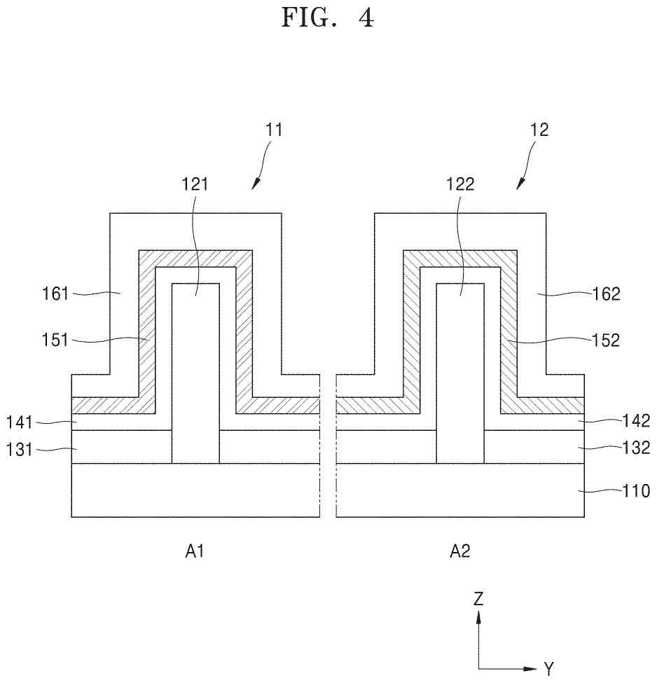

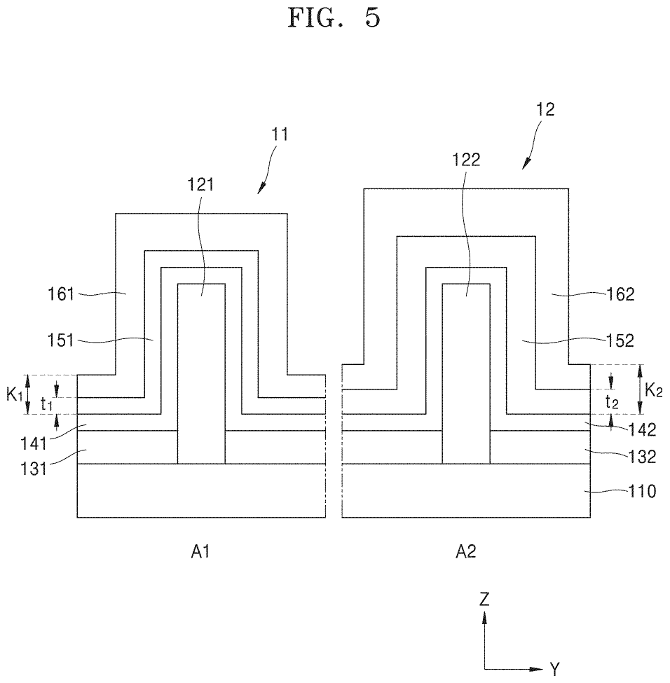

FIG. 4 is a cross-sectional view taken along line A-A of the field effect transistor structure 10 of FIG. 1, according to another embodiment. FIG. 5 is a cross-sectional view taken along line A-A of the field effect transistor structure 10 of FIG. 1, according to another embodiment.

Referring to FIGS. 1, 4 and 5, a field effect transistor structure 10 according to an embodiment may include a substrate 110, a channel 120 on the substrate 110, a source electrode S and a drain electrode D on both sides of the channel 120, a gate insulating film 140, a 2D semiconductor material layer 150, and a gate electrode 160 arranged to be insulated from the source electrode S and the drain electrode D. Configurations other than the 2D semiconductor material layer 150 are substantially the same as those described with reference to FIG. 2, and thus, descriptions thereof will be omitted for convenience of description.

Referring to FIG. 4, according to an embodiment, a first field effect transistor 11 arranged in the first region A1 and a second field effect transistor 12 arranged in the second region A2 may perform functions different from each other. As an example, the first field effect transistor 11 may be an N-type metal-oxide-semiconductor field-effect transistor (NMOSFET), while the second field effect transistor 12 may be a P-type MOSFET (PMOSFET). At this time, a first threshold voltage Vₜₕ₁ of the first field effect transistor 11 arranged in the first region A1 and a second threshold voltage Vₜₕ₂ of the second field effect transistor 12 arranged in the second region A2 may be different from each other.

According to an embodiment, in order to individually control the first threshold voltage Vₜₕ₁ of the first field effect transistor 11 and the second threshold voltage Vₜₕ₂ of the second field effect transistor 12, the compositions of a 2D semiconductor material included in the first 2D semiconductor material layer 151 and the second 2D semiconductor material layer 152 may be different from each other.

As an example, the first threshold voltage Vₜₕ₁ of the first field effect transistor 11 and the second threshold voltage Vₜₕ₂ of the second field effect transistor 12 may be controlled to be different from each other by including a 2D hexagonal boron nitride (h-BN) material in the second 2D semiconductor material layer 152, while including a graphene material in the first 2D semiconductor material layer 151. Accordingly, a threshold voltage Vth for a field effect transistor may be controlled by changing the composition of a material included in the 2D semiconductor material layer 150 without changing the gate electrode 160.

According to another embodiment, it is also possible to differently control the first threshold voltage Vₜₕ₁ of the first field effect transistor 11 and the second threshold voltage Vₜₕ₂ of the second field effect transistor 12 by arranging a 2D semiconductor material layer on only one of the first field effect transistor 11 and the second field effect transistor 12. As an example, it is also possible to differently control the first threshold voltage Vₜₕ₁ of the first field effect transistor 11 and the second threshold voltage Vₜₕ₂ of the second field effect transistor 12 by arranging the second 2D semiconductor material layer 152 in the second field effect transistor 12 without arranging the separate first 2D semiconductor material layer 151 in the first field effect transistor 11.

Referring to FIG. 5, according to an embodiment, in order to differently control the first threshold voltage Vₜₕ₁ of the first field effect transistor 11 arranged in the first region A1 and the second threshold voltage Vₜₕ₂ of the second field effect transistor 12 arranged in the second region A2, thicknesses of the first 2D semiconductor material layer 151 and the second 2D semiconductor material layer 152 may be controlled differently. In FIG. 5, the compositions of the first 2D semiconductor material layer 151 and the second 2D semiconductor material layer 152 may be the same or different from each other, based on independently selecting any one of the materials described above as suitable for the 2D semiconductor material layer 150.

As an example, the first 2D semiconductor material layer 151 may be provided with a first thickness t₁, while the second 2D semiconductor material layer 152 may be provided with a second thickness t₂ different from the first thickness t₁. Accordingly, the sum K₁ of thicknesses of the first gate electrode 161 and the first 2D semiconductor material layer 151 and the sum K₂ of thicknesses of the second gate electrode 162 and the second 2D semiconductor material layer 152 may be formed differently. Accordingly, the first threshold voltage Vₜₕ₁ of the first field effect transistor 11 and the second threshold voltage Vₜₕ₂ of the second field effect transistor 12 may be controlled to be different from each other. Accordingly, a threshold voltage Vth for a field effect transistor may be controlled by changing the thickness t of a material included in the 2D semiconductor material layer 150 without changing the gate electrode 160.

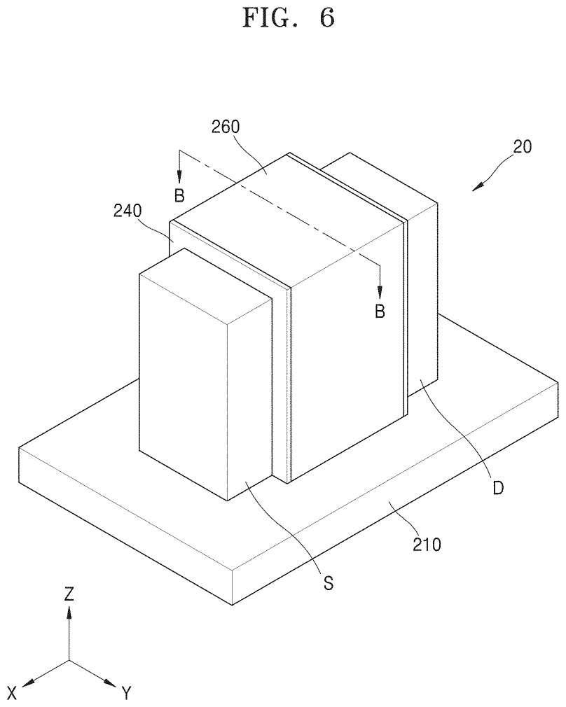

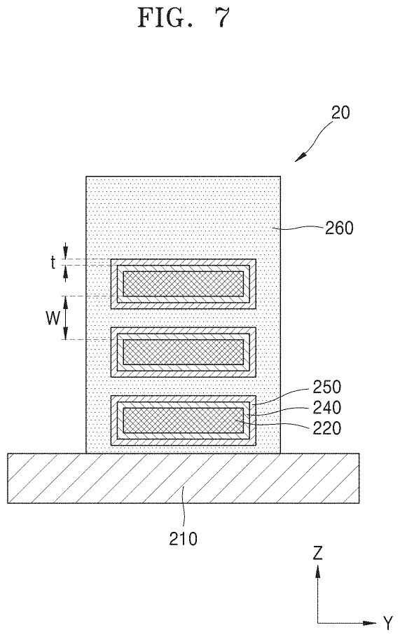

FIG. 6 is a schematic perspective view showing a field effect transistor structure 20 according to another embodiment. FIG. 7 is a cross-sectional view taken along line B-B of the field effect transistor structure 20 of FIG. 6. The cross-section B-B may represent a cross-section cut in a vertical direction to a substrate 210 (the Z-direction in the drawing) across (the Y-direction in the drawing) between the source electrode S and the drain electrode D. Here, because the substrate 210 may not be completely planar, the vertical direction may include a substantially vertical direction as well as a general vertical direction.

Referring to FIGS. 6 and 7, the field effect transistor structure 20 according to another embodiment may include a substrate 210, a source electrode S on the substrate 210, a drain electrode D separated from the source electrode S, a channel 220 connected between the source electrode S and the drain electrode D, a gate insulating film 240, a 2D semiconductor material layer 250, and a gate electrode 260 to be insulated from the source electrode S and the drain electrode D.

The substrate 210 may include an insulating substrate, or may include a semiconductor substrate having an insulating layer on a surface thereof. The semiconductor substrate may include, for example, Si, Ge, SiGe or a Group III-V semiconductor material, and the like. The substrate 210 may include, for example, a silicon substrate in which a silicon oxide is formed on a surface thereof, but is not limited thereto.

The channel 220 may extend in a one direction parallel to the substrate 210. As an example, the channel 220 may be provided in the form of a nanowire extending in one direction or in the form of a nano-sheet extending along a plane. The channel 220 according to the present embodiment may be provided in a plural number. The plurality of channels 220 may be arranged to be separated from each other in a direction perpendicular to the substrate 210 (the Z-direction). In other words, the neighboring channels 220 may be arranged separately from each other in the first direction (the Z-direction). The channel 220 may directly contact the source electrode S and the drain electrode D. However, the present disclosure is not limited thereto, and it is also possible that the channel 220 is connected to the source electrode S and the drain electrode D through the other mediators.

The gate insulating film 240 may be arranged to surround the channel 220. The gate electrode 260, which will be described later, may be insulated from the source electrode S and the drain electrode D by the gate insulating film 240. The gate insulating film 240 may include a dielectric film having a high dielectric constant (high-k). The gate insulating film 240 may include, for example, one or more of a metal-oxide including HF or Zr, a metal-oxide-nitride including HF or Zr, or a material that is formed by doping Ti, Ta, Al, or a lanthanide-based material to the above materials.

The gate electrode 260 may be arranged on the gate insulating film 240 and may be provided in the form of surrounding the channel 220. As an example, the gate electrode 260 may be arranged to surround the entire sides of the channel 220. Accordingly, the field effect transistor structure 20 according to the present embodiment may be provided as a field effect transistor of an gate-all-around structure (GAA FET). As an example, the gate electrode 260 may include one or more of a metal, a metal-carbide, a metal-nitride, a metal-silicide, a metal-silicon-nitride, silicon, and a graphene material. At this time, the gate electrode 260 may have a desired and/or alternatively predetermined work function. A threshold voltage of the field effect transistor structure 20 according to the present embodiment may be controlled by using the work function of the gate electrode 260.

As described above, according to the present embodiment, the field effect transistor structure 20 may be provided as a 3D structure, such as a field effect transistor of an all-around gate structure. Due to the 3D shape of the field effect transistor structure 20, a reliable control of the work function of the gate electrode 260 may be difficult. As an example, in order to improve the degree of integration of the field effect transistor structure 20, a gap W between the plurality of channels 220 may be reduced. At this time, in a process of depositing the gate electrode 260 between the plurality of channels 220, the reliable deposition of the gate electrode 260 for controlling the work function may be difficult. According to the present embodiment, in the field effect transistor structure 20 provided in a 3D structure, in order to control a threshold voltage of the field effect transistor structure 20, the 2D semiconductor material layer 250 may be arranged between the gate insulating film 240 and the gate electrode 260.

The 2D semiconductor material layer 250 may be arranged between the gate insulating film 240 and the gate electrode 260 to control a threshold voltage of the field effect transistor structure 20. As an example, the 2D semiconductor material layer 250 may include a graphene, a 2D hexagonal boron nitride (h-BN), black phosphorus, phosphorene, or transition metal dichalcogenide. As an example, an amorphous boron nitride or the 2D hexagonal boron nitride (h-BN) may have a grain size of about 20 nm or less. In addition, the transition metal dichalcogenide may include one or more metal element selected from the group consisting of Mo, W, Nb, V, Ta, Ti, Zr, Hf, Tc, Re, Cu, Ga, In, Sn, Ge, and Pb and one or more chalcogen element selected from the group consisting of S, Se, and Te. On the other hand, a desired and/or alternatively predetermined conductive dopant may be doped to a 2D semiconductor material.

As described with reference to FIG. 3, and referring to FIGS. 6-7, when the 2D semiconductor material layer 250 is arranged to overlap with the gate electrode 260, the work function of the 2D semiconductor material layer 250 and the gate electrode 260 may be reduced and/or adjusted. Accordingly, the work function may be reduced by disposing the 2D semiconductor material layer 250 in the form of an ultra-thin film on the gate electrode 260, and accordingly, a threshold voltage of the field effect transistor structure 20 may be controlled.

As an example, the 2D semiconductor material layer 250 may extend along an outer side of the gate insulating film 240. The 2D semiconductor material layer 250 according to the present embodiment may be provided in the form of an ultra-thin film as described above. For example, the thickness t of the 2D semiconductor material layer 250 may be about 3 nm or less. For example, the thickness t of the 2D semiconductor material layer 250 may be about 2 nm or less. For example, the thickness t of the 2D semiconductor material layer 250 may be about 1 nm or less.

According to one example, in order to improve the degree of integration of the field effect transistor structure 20, the gap W between the plurality of channels 220 may be reduced. However, as the 2D semiconductor material layer 250 according to the present embodiment is provided in the form of an ultra-thin film, the 2D semiconductor material layer 250 may be easily arranged between the plurality of channels 220. Accordingly, the threshold voltage of the field effect transistor structure 20 may be controlled without changing the gate electrode 260.

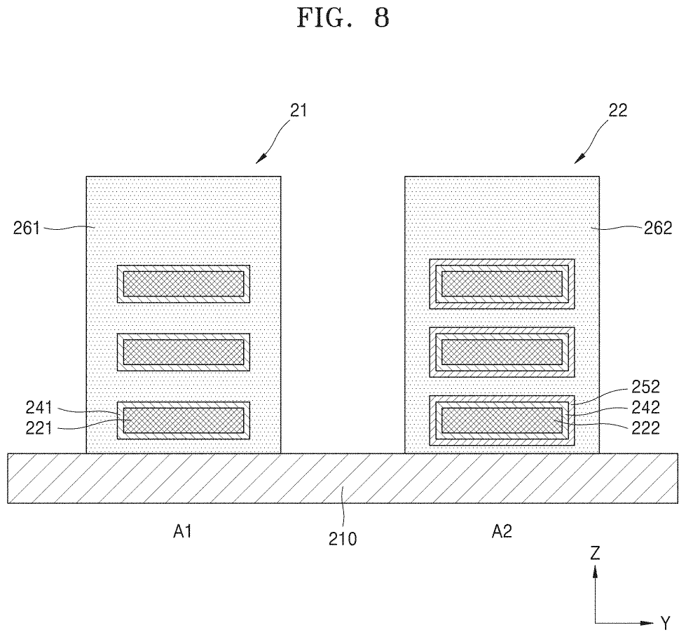

Although the field effect transistor structure 20 shown in FIGS. 6 and 7 includes a single field effect transistor, inventive concepts are not limited thereto. The field effect transistor structure 20 according to the present embodiment may include two or more field effect transistors. In the field effect transistor structure 20 according to the present embodiment, as shown in FIGS. 8 to 10, a first field effect transistor 21 and a second field effect transistor 22 may be respectively arranged in the first region A1 and the second region A2 on the substrate 210. Hereinafter, a technical feature of individually controlling threshold voltages of the first field effect transistor 21 arranged in the first region A1 and the second field effect transistor 22 arranged in the second region A2 will be described by using a first 2D semiconductor material layer 251 and a second 2D semiconductor material layer 252 respectively arranged in the first region A1 and the second region A2.

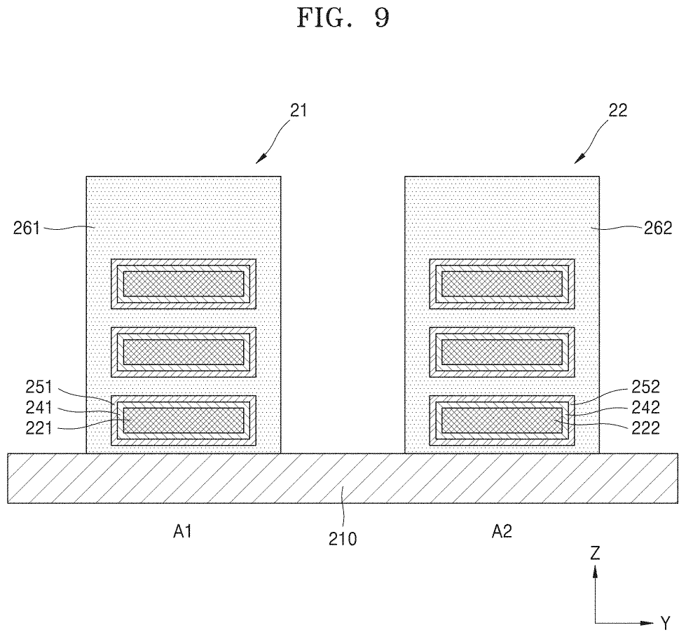

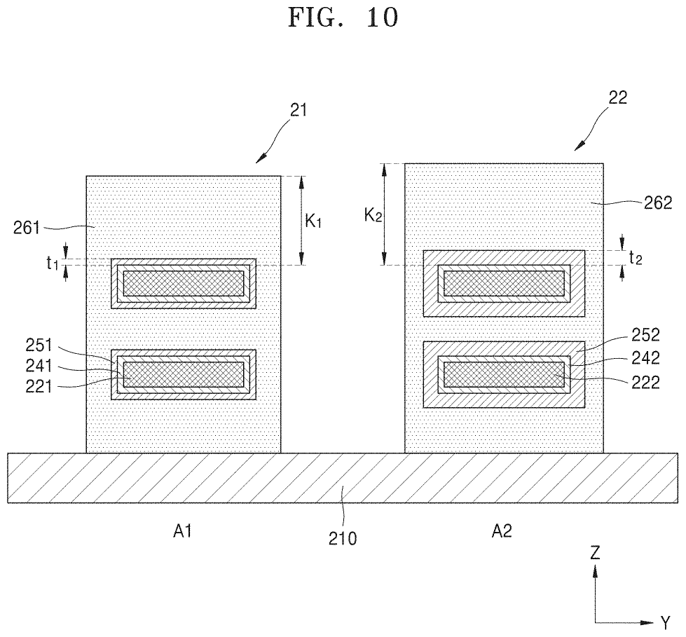

FIG. 8 is a schematic cross-sectional view of a field effect transistor structure according to another embodiment. FIG. 9 is a schematic cross-sectional view of a field effect transistor structure according to another embodiment. FIG. 10 is a schematic cross-sectional view of a field effect transistor structure according to another embodiment.

Referring to FIGS. 8 and 9, the field effect transistor structure 20 according to the present embodiment may include a first field effect transistor 21 and a second field effect transistor 22 respectively arranged in a first region A1 and a second region A2. The first field effect transistor 21 may include: a first source electrode (not shown) arranged on the substrate 210; a first drain electrode (not shown) arranged separately from the first source electrode; a first channel 221, a first gate insulating film 241, and a first 2D semiconductor material layer 251 that are connected between the first source electrode and the first drain electrode; and a first gate electrode 261 arranged to be insulated from the first source electrode and the first drain electrode. Also, the second field effect transistor 22 may include: a second source electrode (not shown) arranged on the substrate 210; a second drain electrode (not shown) arranged to be separated from the second source electrode; a second channel 222, a second gate insulating film 242, and a second 2D semiconductor material layer 252 that are connected between the second source electrode and the second drain electrode; and a second gate electrode 262 arranged to be insulated from the second source electrode and the second drain electrode. Descriptions for the first and second source electrodes, the first and second drain electrodes, the first and second channels 221 and 222, the first and second gate insulating films 241 and 242, and the first and second 2D semiconductor material layers 251 and 252 may be substantially the same as the descriptions for the source electrode S, the drain electrode D, the channel 220, the gate insulating film 240, the 2D semiconductor material layer 250, and the gate electrode 260 shown in FIG. 7, and thus, the descriptions thereof will be omitted.

Referring to FIGS. 8 and 9, according to the present embodiment, the first field effect transistor 21 arranged in the first region A1 and the second field effect transistor 22 arranged in the second region A2 may perform different functions from each other. As an example, the first field effect transistor 21 may be an N-type metal-oxide-semiconductor field-effect transistor (NMOSFET), while the second field effect transistor 22 may be a P-type MOSFET (PMOSFET). At this time, a first threshold voltage Vₜₕ₁ of the first field effect transistor 21 arranged in the first region A1 and a second threshold voltage Vₜₕ₂ of the second field effect transistor 22 arranged in the second region A2 may be different from each other.

According to one example, in order to individually control the first threshold voltage Vₜₕ₁ of the first field effect transistor 21 and the second threshold voltage Vₜₕ₂ of the second field effect transistor 22, the first threshold voltage Vₜₕ₁ of the first field effect transistor 21 and the second threshold voltage Vₜₕ₂ of the second field effect transistor 22 may be differently controlled by arranging a 2D semiconductor material layer on only one of the first field effect transistor 21 and the second field effect transistor 22, as shown in FIG. 8. As an example, it is also possible to differently control the first threshold voltage Vₜₕ₁ of the first field effect transistor 21 and the second threshold voltage Vₜₕ₂ of the second field effect transistor 22 by arranging the second 2D semiconductor material layer 252 in the second field effect transistor 22 without arranging a separate first 2D semiconductor material layer in the first field effect transistor 21.

According to another embodiment, in order to individually control the first threshold voltage Vₜₕ₁ of the first field effect transistor 21 and the second threshold voltage Vₜₕ₂ of the second field effect transistor 22, as shown in FIG. 9, the compositions of a 2D semiconductor material included in the first 2D semiconductor material layer 251 and the second 2D semiconductor material layer 252 may be controlled differently from each other.

As an example, the first threshold voltage Vₜₕ₁ of the first field effect transistor 21 and the second threshold voltage Vₜₕ₂ of the second field effect transistor 22 may be controlled to be different from each other by including a 2D hexagonal boron nitride (h-BN) material in the second 2D semiconductor material layer 252, while including a graphene material in the first 2D semiconductor material layer 251. Therefore, a threshold voltage Vth for a field effect transistor may be controlled by changing the composition of a material included in the first 2D semiconductor material layer 251 and the second 2D semiconductor material layer 252 without changing the first gate electrode 261 and the second gate electrode 262.

Referring to FIG. 10, according to an embodiment, in order to differently control the first threshold voltage Vₜₕ₁ of the first field effect transistor 21 arranged in the first region A1 and the second threshold voltage Vₜₕ₂ of the second field effect transistor 22 arranged in the second region A2, thicknesses of the first 2D semiconductor material layer 251 and the second 2D semiconductor material layer 252 may be controlled differently. In FIG. 10, the compositions of the first 2D semiconductor material layer 251 and the second 2D semiconductor material layer 252 may be the same or different from each other, based on independently selecting any one of the materials described above as suitable for the 2D semiconductor material layer 250.

As an example, the first 2D semiconductor material layer 251 may be provided with a first thickness t₁, while the second 2D semiconductor material layer 252 may be provided with a second thickness t₂ different from the first thickness t₁. Accordingly, the sum K₁ of thicknesses of the first gate electrode 161 and the first 2D semiconductor material layer 251 and the sum K₂ of thicknesses of the second gate electrode 262 and the second 2D semiconductor material layer 252 may be formed differently. Accordingly, the first threshold voltage Vₜₕ₁ of the first field effect transistor 21 and the second threshold voltage Vₜₕ₂ of the second field effect transistor 22 may be controlled to be different from each other. Accordingly, a threshold voltage Vth for a field effect transistor may be controlled by changing the thicknesses t₁ and t₂ of the first 2D semiconductor material layer 251 and the second 2D semiconductor material layer 252 without changing the first gate electrode 261 and the second gate electrode 262.

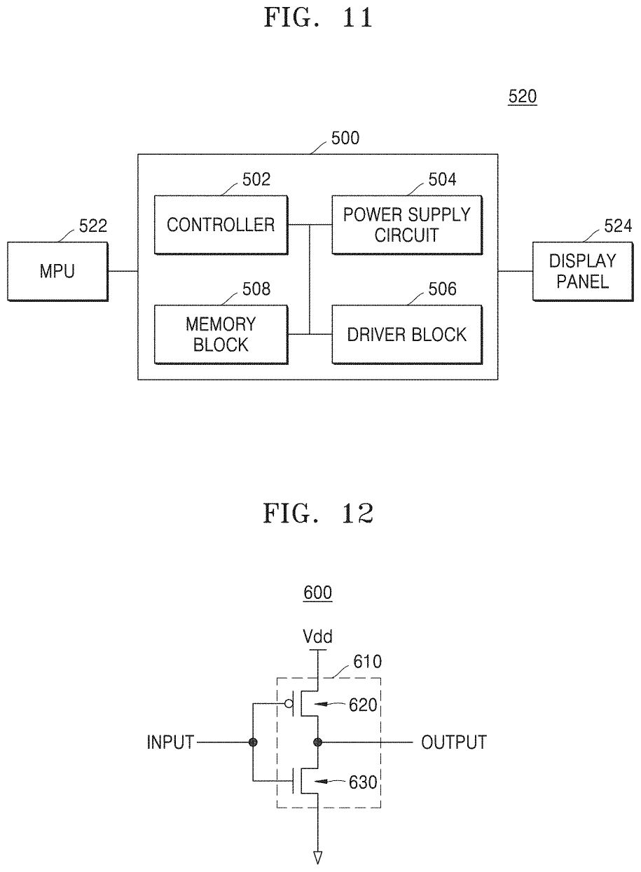

FIG. 11 is a schematic block diagram of a display device 520 including a display driver integrated circuit (DDIC) 500 and a DDI 500 according to an embodiment.

Referring to FIG. 11, the DDI 500 may include a controller 502, a power supply circuit 504, a driver block 506, and a memory block 508. The controller 502 receives and decodes a command applied from a main processing unit (MPU) 522, and controls each block of the DDI 500 to implement an operation in response to the command. The power supply circuit 504 generates a driving voltage in response to the control of the controller 502. The driver block 506 drives a display panel 524 by using a driving voltage generated by the power supply circuit 504 in response to the control of the controller 502. The display panel 524 may include a liquid crystal display panel or a plasma display. The memory block 508 may be a block for temporarily storing commands input to the controller 502 or control signals output from the controller 502 or for storing necessary data, and may include a memory, such as RAM or ROM. The power supply circuit 504 and the driver block 506 may include a field effect transistor structure according to an embodiment described above with reference to FIGS. 1 to 10.

FIG. 12 is a circuit diagram of a CMOS inverter 600 according to an embodiment.

The CMOS inverter 600 includes a CMOS transistor 610. The CMOS transistor 610 includes a PMOS transistor 620 and an NMOS transistor 630 connected between a power terminal Vdd and a ground terminal. The CMOS transistor 610 may include a field effect transistor structure according to an embodiment described above with reference to FIGS. 1 to 10.

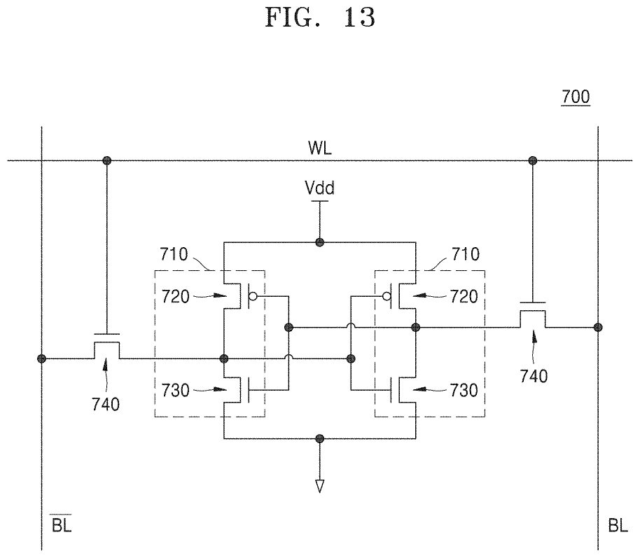

FIG. 13 is a circuit diagram of a CMOS SRAM device 700 according to an embodiment.

The CMOS SRAM device 700 includes a pair of driving transistors 710. The pair of driving transistors 710 includes a PMOS transistor 720 and an NMOS transistor 730 connected between the power terminal Vdd and the ground terminal, respectively. The CMOS SRAM element 700 may further include a pair of transfer transistors 740. A source of the transfer transistor 740 is cross-connected to a common node of the PMOS transistor 720 and the NMOS transistor 730 constituting the driving transistor 710. A power terminal Vdd is connected to the source of the PMOS transistor 720, and a ground terminal is connected to the source of the NMOS transistor 730. A word line WL may be connected to a gate of the pair of transfer transistors 740, and a bit line BL and an inverted bit line may be respectively connected to a drain of each of the pair of transfer transistors 740.

At least one of the driving transistor 710 and the transfer transistor 740 of the CMOS SRAM device 700 may include a field effect transistor structure according to an embodiment described above with reference to FIGS. 1 to 10.

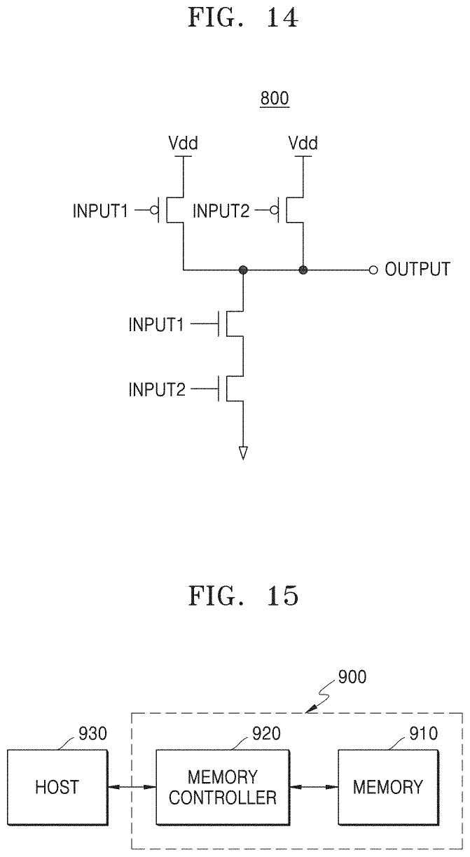

FIG. 14 is a circuit diagram of a CMOS NAND circuit 800 according to an embodiment.

The CMOS NAND circuit 800 includes a pair of CMOS transistors to which different input signals are transmitted. The CMOS NAND circuit 800 may include a field effect transistor structure according to an embodiment described above with reference to FIGS. 1 to 10.

FIG. 15 is a block diagram of an electronic system 900 according to an embodiment.

The electronic system 900 includes a memory 910 and a memory controller 920. The memory controller 920 may control the memory 910 for data reading from memory 910 and/or data writing to the memory 910 in response to a request of a host 930. At least one of the memory 910 and the memory controller 920 may include a field effect transistor structure according to an embodiment described above with reference to FIGS. 1 to 10.

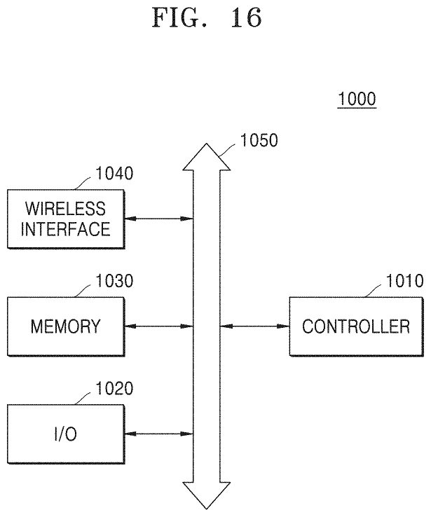

FIG. 16 is a block diagram of an electronic system 1000 according to an embodiment.

The electronic system 1000 may constitute a wireless communication device, or a device capable of transmitting and/or receiving information in a wireless environment. The electronic system 1000 includes a controller 1010, an input/output (I/O) device 1020, a memory 1030, and a wireless interface 1040, which are interconnected through a bus 1050.

The controller 1010 may include at least one of a microprocessor, a digital signal processor, or a processing apparatus similar thereto. The I/O device 1020 may include at least one of a keypad, a keyboard, or a display. The memory 1030 may be used to store commands executed by the controller 1010. For example, the memory 1030 may be used to store a user data. The electronic system 1000 may use the wireless interface 1040 to transmit/receive data through a wireless communication network. The wireless interface 1040 may include an antenna and/or a wireless transceiver. In some embodiments, the electronic system 1000 may be used for a communication interface protocol of a third generation communication system, for example, a code division multiple access (CDMA), a global system for mobile communications (GSM), a north American digital cellular (NADC), an extended-time division multiple access (E-TDMA), and/or a wide band code division multiple access (WCDMA). The electronic system 1000 may include a field effect transistor structure according to an embodiment described above with reference to FIGS. 1 to 10.

The field effect transistor structure according to the present disclosure may exhibit a favorable electrical performance with an ultra-small structure, and thus may be applied to an integrated circuit device, and may realize miniaturization, low power, and high performance.

The field effect transistor structure according to the present disclosure may reduce a threshold voltage without changing the shape of the gate electrode by arranging a 2D semiconductor material layer.

The field effect transistor structure according to the present disclosure may reduce a short channel effect while reducing the size of the field effect transistor structure.

The field effect transistor structure according to the present disclosure may have various threshold voltages by changing the composition ratio of the 2D semiconductor material layer.

The field effect transistor structure according to the present disclosure may have various threshold voltages by changing the thickness of the 2D semiconductor material layer.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A field effect transistor structure comprising:
a fin-shaped channel protruding from a substrate and extending in one direction;
a source electrode on one side of the fin-shaped channel;
a drain electrode separated from the source electrode with the fin-shaped channel therebetween;
a gate insulating film surrounding side surfaces of the fin-shaped and upper surfaces of the fin-shaped channel;
a gate electrode on the gate insulating film; and
a two-dimensional semiconductor material layer between the gate insulating film and the gate electrode.

2. The field effect transistor structure of claim 1,
wherein the two-dimensional semiconductor material layer has a thickness of about 3 nm or less.

3. The field effect transistor structure of claim 1,
wherein the gate electrode includes one or more of a metal, a metal-carbide, a metal-nitride, a metal-silicide, a metal-silicon-nitride, silicon, and a graphene-based material.

4. The field effect transistor structure of claim 1,
wherein the two-dimensional semiconductor material layer includes at least one of graphene, black phosphorus, amorphous boron nitride, two-dimensional hexagonal boron nitride (h-BN), phosphorene, or a transition metal dichalcogenide.

5. The field effect transistor structure of claim 4, wherein
the transition metal dichalcogenide includes one metal element and one chalcogen element,
the one metal element is selected from the group consisting of Mo, W, Nb, V, Ta, Ti, Zr, Hf, Tc, Re, Cu, Ga, In, Sn, Ge, and Pb, and
the one chalcogen element is selected from the group consisting of S, Se, and Te.

6. The field effect transistor structure of claim 1, wherein the two-dimensional semiconductor material layer includes:
amorphous boron nitride having a grain size of about 20 nm or less, or
two-dimensional hexagonal boron nitride having a grain size of about 20 nm or less.

7. A field effect transistor structure comprising:
a first field effect transistor and a second field effect transistor adjacent to each other,
the first field effect transistor including a fin-shaped first channel protruding from a substrate and extending in one direction, a first source electrode on one side of the fin-shaped first channel, a first drain electrode separated from the first source electrode with the fin-shaped first channel therebetween, a first gate insulating film surrounding side and upper surfaces of the fin-shaped first channel, and a first gate electrode on the first gate insulating film,
the second field effect transistor including a fin-shaped second channel protruding from the substrate and extending in the one direction, a second source electrode on one side of the fin-shaped second channel, a second drain electrode separated from the second source electrode with the fin-shaped second channel therebetween, a second gate insulating film surrounding side and upper surfaces of the fin-shaped second channel, a second gate electrode on the second gate insulating film, and a second two-dimensional semiconductor material layer between the second gate insulating film and the second gate electrode.

8. The field effect transistor structure of claim 7, wherein
the first field effect transistor further comprises a first two-dimensional semiconductor material layer between the first gate insulating film and the first gate electrode, and
the first two-dimensional semiconductor material layer and the second two-dimensional semiconductor material layer include different two-dimensional semiconductor materials.

9. The field effect transistor structure of claim 7, wherein
the first field effect transistor further comprises a first two-dimensional semiconductor material layer between the first gate insulating film and the first gate electrode, and
the first two-dimensional semiconductor material layer and the second two-dimensional semiconductor material layer have different thicknesses.

10. The field effect transistor structure of claim 8,
wherein the first two-dimensional semiconductor material layer and the second two-dimensional semiconductor material layer each have a thickness of about 3 nm or less.

11. A field effect transistor structure comprising:
a channel extending in one direction parallel to a substrate;
a source electrode on one side of the channel;
a drain electrode separated from the source electrode with the channel therebetween;
a gate insulating film surrounding the channel;
a gate electrode on the gate insulating film; and
a two-dimensional semiconductor material layer between the gate insulating film and the gate electrode.

12. The field effect transistor structure of claim 11,
wherein the channel is one channel among a plurality of channels arranged in a direction perpendicular to the substrate.

13. The field effect transistor structure of claim 11,
wherein the two-dimensional semiconductor material layer has a thickness of about 3 nm or less.

14. The field effect transistor structure of claim 11,
wherein the gate electrode includes one or more of a metal, a metal-carbide, a metal-nitride, a metal-silicide, a metal-silicon-nitride, silicon, and a graphene-based material.

15. The field effect transistor structure of claim 11,
wherein the two-dimensional semiconductor material layer includes one or more of graphene, black phosphorus, amorphous boron nitride, two-dimensional hexagonal boron nitride (h-BN), phosphorene, or a transition metal dichalcogenide.

16. The field effect transistor structure of claim 15, wherein
the transition metal dichalcogenide includes one metal element and one chalcogen element,
the one metal element is selected from the group consisting of Mo, W, Nb, V, Ta, Ti, Zr, Hf, Tc, Re, Cu, Ga, In, Sn, Ge, and Pb, and
the one chalcogen element is selected from the group consisting of S, Se, and Te.

17. The field effect transistor structure of claim 15, wherein the two-dimensional semiconductor material layer includes:
amorphous boron nitride having a grain size of about 20 nm or less, or
two-dimensional hexagonal boron nitride having a grain size of about 20 nm or less.

18. The field effect transistor structure of claim 11,
wherein the channel has a nanowire shape extending in one direction.

19. The field effect transistor structure of claim 11,
wherein the channel has a nano-sheet shape extending along one plane.

20. A field effect transistor structure comprising:
a first field effect transistor and a second field effect transistor adjacent to each other,
the first field effect transistor including a first channel extending in one direction parallel to a substrate, a first source electrode on one side of the first channel, a first drain electrode separated from the first source electrode with the first channel therebetween, a first gate insulating film surrounding the first channel, and a first gate electrode on the first gate insulating film, and
the second field effect transistor including a second channel extending in the one direction parallel to the substrate, a second source electrode on one side of the first channel, a second drain electrode separated from the second source electrode with the second channel therebetween, a second gate insulating film surrounding the first channel, a second gate electrode on the second gate insulating film, and a second two-dimensional semiconductor material layer between the second gate insulating film and the second gate electrode.

21. The field effect transistor structure of claim 20,
wherein the first field effect transistor further comprises a first two-dimensional semiconductor material layer between the first gate insulating film and the first gate electrode, and
the first two-dimensional semiconductor material layer and the second two-dimensional semiconductor material layer include different two-dimensional semiconductor materials.

22. The field effect transistor structure of claim 20,
wherein the first field effect transistor further comprises a first two-dimensional semiconductor material layer between the first gate insulating film and the first gate electrode, and
the first two-dimensional semiconductor material layer and the second two-dimensional semiconductor material layer have different thicknesses.

23. The field effect transistor structure of claim 21,
wherein the first two-dimensional semiconductor material layer and the second two-dimensional semiconductor material layer each have a thickness of about 3 nm or less.
